(19) United States
(12) Patent Application Publication
(10) Pub. No.: US 2024/0313089 A1
(43) Pub. Date: Sep. 19, 2024

(54) NITRIDE SEMICONDUCTOR DEVICE AND FABRICATION METHOD THEREOF

(71) Applicant: FUJI ELECTRIC CO., LTD., Kawasaki-shi (JP)

(72) Inventors: Ryo TANAKA, Hino-city (JP); Katsunori UENO, Matsumoto-city (JP); Shinya TAKASHIMA, Hachioji-city (JP)

(73) Assignee: FUJI ELECTRIC CO., LTD., Kawasaki-shi (JP)

(21) Appl. No.: 18/422,787

(22) Filed: Jan. 25, 2024

(30) Foreign Application Priority Data
Mar. 15, 2023 (JP) 2023-041140

(51) Int. Cl. H01L 29/66; H01L 21/225; H01L 21/265; H01L 21/266; H01L 29/08; H01L 29/20; H01L 29/78

(52) U.S. Cl. CPC H01L 29/66522; H01L 21/2258; H01L 21/26546; H01L 21/266; H01L 29/086; H01L 29/2003; H01L 29/66712; H01L 29/7802

(57) ABSTRACT

The nitride semiconductor device includes a field effect transistor formed in a gallium nitride layer. The field effect transistor includes: a gate insulator film formed on a side of a first principal face of the gallium nitride layer; a p type region being in contact with the gate insulator film; an n type region being in contact with the p type region in a direction parallel to an interface between the p type region and the gate insulator film; a first electrode being in contact with the n type region. The p type region includes a first region that is in contact with the gate insulator film and a second region that is in contact with the gate insulator film and lies in the first direction between the first region and the n type region. The second region has a higher concentration of p type impurities than the first region.

### CROSS REFERENCE TO RELATED APPLICATIONS AND INCORPORATION BY REFERENCE

This application claims benefit of priority under 35 USC 119 based on Japanese Patent Application No. 2023-041140 filed on Mar. 15, 2023, the entire contents of which are incorporated by reference herein.

### TECHNICAL FIELD

The present invention relates to a nitride semiconductor device and a fabrication method thereof.

### BACKGROUND ART

Traditionally, there have been known vertical MOSFETS that employ gallium nitride (GaN) (see, for example, JP 2017-188687 A).

### SUMMARY OF INVENTION

### Technical Problem

In order to improve a property of a vertical MOSFET employing GaN, a balance needs to be achieved between high threshold voltage and high mobility. In general, threshold voltage and mobility are in a trade-off relationship. For example, if concentration in a p type well region is increased in order to increase threshold voltage, mobility will decrease.

It is an object of the present disclosure to provide a nitride semiconductor device that achieves a good balance between high threshold voltage and high mobility and a fabrication method of the nitride semiconductor device.

### Solution to Problem

In order to achieve the above-described object, according to an aspect of the present disclosure, there is provided a nitride semiconductor device, including: a gallium nitride layer having a first principal face and a second principal face, the second principal face being located on opposite side of the first principal face; and a field effect transistor formed in the gallium nitride layer, the field effect transistor including: a gate insulator film formed on the gallium nitride layer on a side of the first principal face; a p type region formed in the gallium nitride layer, the p type region being in contact with the gate insulator film; an n type region formed in the gallium nitride layer, the n type region being in contact with the p type region in a first direction parallel to an interface between the p type region and the gate insulator film; and a first electrode disposed on the side of the first principal face, the first electrode being in contact with the n type region, wherein the p type region includes: a first region being in contact with the gate insulator film; and a second region being in contact with the gate insulator film and lying in the first direction between the first region and the n type region, wherein the second region has a higher concentration of p type impurities than the first region.

According to another aspect of the present disclosure, there is provided a fabrication method of a nitride semiconductor device, including: forming a p type region in a gallium nitride layer; forming, in the gallium nitride layer, a high-concentration region in a region being in contact with the p type region, the high-concentration region having a higher concentration of p type impurities than the p type region; forming, by heat-treating the gallium nitride layer to diffuse p type impurities from the high-concentration region to the p type region, a second region having a higher concentration of p type impurities than a first region of the p type region; forming a gate insulator film on the gallium nitride layer on a side of a first principal face, the gate insulator film being in contact with the first region and the second region; forming an n type region in the gallium nitride layer on the side of the first principal face opposite to the first region across the second region; and forming a first electrode, the first electrode being in contact with the n type region.

### Advantageous Effects of Invention

According to the aspects of the present disclosure, to provide a nitride semiconductor device that achieves a good balance between high threshold voltage and high mobility and a fabrication method of the nitride semiconductor device.

### BRIEF DESCRIPTION OF DRAWINGS

FIG. 1 is a plan view illustrating an example structure of a GaN semiconductor device according to a first embodiment of the present disclosure;

FIG. 2 is a cross-sectional diagram illustrating an example structure of the GaN semiconductor device according to the first embodiment of the present disclosure;

FIG. 3 is an enlarged view of a portion of the cross-sectional diagram of FIG. 2;

FIG. 4 is a graph illustrating a distribution of impurity concentration in a vertical MOSFET illustrated in FIG. 3 along line B-B′;

FIGS. 5A to 5D are cross-sectional diagrams illustrating a fabrication method of the vertical MOSFET according to the first embodiment of the present disclosure step by step;

FIG. 6 is a cross-sectional diagram illustrating an example structure of a vertical MOSFET according to a second embodiment of the present disclosure;

FIGS. 7A to 7C are cross-sectional diagrams illustrating a fabrication method of the vertical MOSFET according to the second embodiment of the present disclosure step by step;

FIG. 8 is a cross-sectional diagram illustrating an example structure of a vertical MOSFET according to a variation example of the second embodiment of the present disclosure;

FIG. 9 is a cross-sectional diagram illustrating an example structure of a vertical MOSFET according to a third embodiment of the present disclosure;

FIGS. 10A and 10B are cross-sectional diagrams illustrating a fabrication method of the vertical MOSFET according to the third embodiment of the present disclosure step by step;

FIG. 11 is a cross-sectional diagram illustrating an example structure of a vertical MOSFET according to a fourth embodiment of the present disclosure;

FIGS. 12A to 12C are cross-sectional diagrams illustrating a fabrication method of the vertical MOSFET according to the fourth embodiment of the present disclosure step by step;

FIG. 13 is a cross-sectional diagram illustrating an example structure of a vertical MOSFET according to a fifth embodiment of the present disclosure; and

FIGS. 14A to 14E are cross-sectional diagrams illustrating a fabrication method of the vertical MOSFET according to the fifth embodiment of the present disclosure step by step.

### DESCRIPTION OF EMBODIMENTS

Embodiments of the present invention will be described below. In the following description of the drawings, the same or similar portions are denoted by the same or similar reference numerals. However, it should be noted that the drawings are schematic and a relation between a thickness and a flat dimension, a ratio of thicknesses of respective devices or members, and the like are different from actual ones. Accordingly, specific thicknesses and dimensions should be determined with reference to the following description. In addition, it is certain that some portions have different dimensional relations and ratios between the drawings.

In the following description, descriptions relating to directions are sometimes made using wording such as “X-axis direction”, “Y-axis direction”, and “Z-axis direction”. For example, the X-axis direction and the Y-axis direction are directions parallel to a front surface 10a of a GaN substrate 10. The X-axis direction and the Y-axis direction are also referred to as horizontal directions. The Z-axis direction is a normal direction of the front surface 10a. The X-axis direction, the Y-axis direction, and the Z-axis direction intersect one another at right angles.

In the following description, the arrow direction and the opposite direction to the arrow direction of the Z-axis are sometimes referred to as “upper” and “lower”, respectively. The “upper” and the “lower” do not necessarily mean the vertical directions with respect to the ground surface. In other words, the “upper” direction and the “lower” direction are not limited to the directions of gravitational force. The “upper” and the “lower” are nothing more than expressions for the sake of convenience to specify relative positional relations in a region, a layer, a film, a substrate, or the like, and do not limit a technological concept of the present disclosure. For example, it is needless to say that, when the plane of paper is rotated 180 degrees, “upper” and “lower” are exchanged with “lower” and “upper”, respectively.

In the following description, signs + and − attached to P or N, which indicate conductivity types of a semiconductor region, indicate that semiconductor regions to the conductivity types of which the signs + and − are attached are semiconductor regions the impurity concentrations of which are relatively higher and lower than another semiconductor region to the conductivity type of which neither + nor − is attached, respectively. However, two semiconductor regions having the same conductivity type P (or N) assigned thereto does not necessarily mean that the impurity concentrations of the semiconductor regions are exactly the same.

### First Embodiment

### (Example Structure)

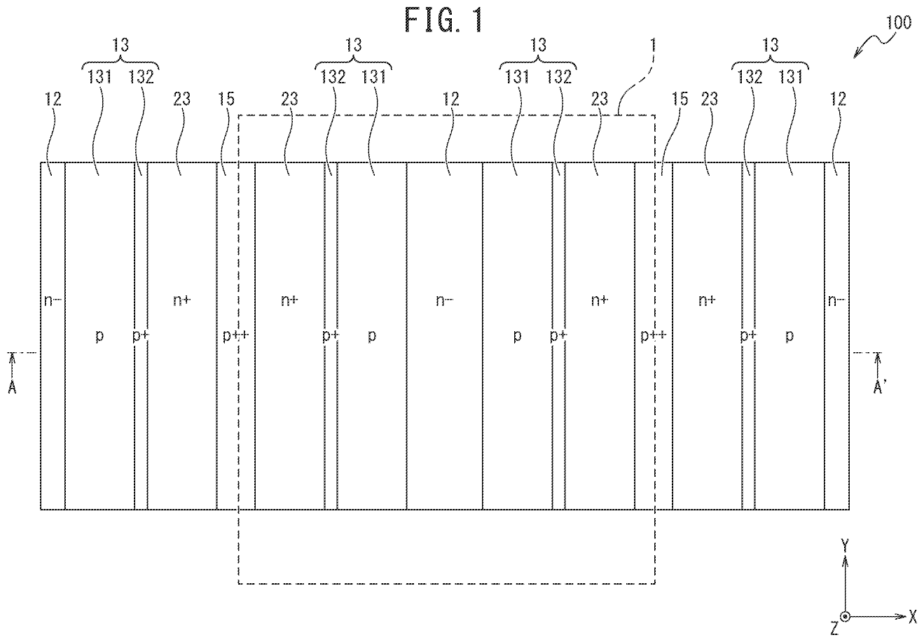

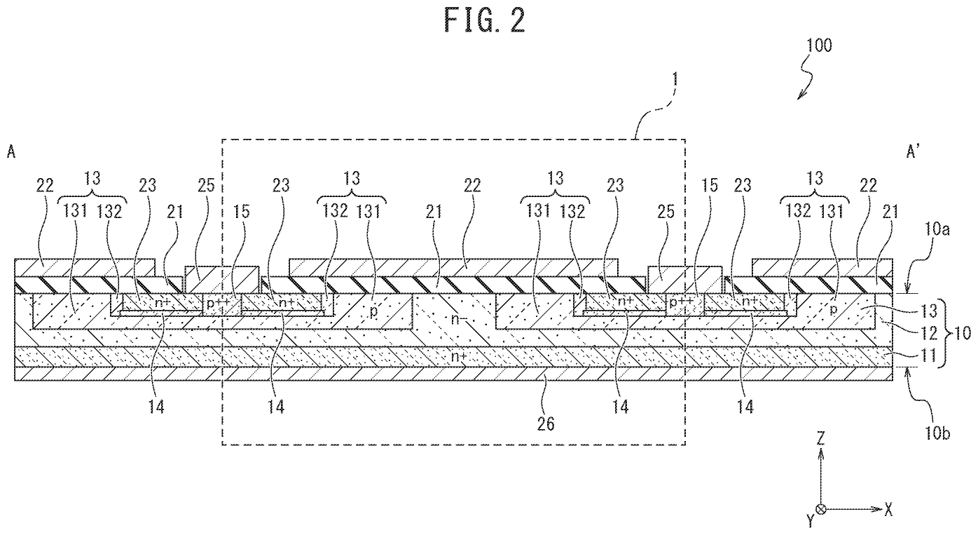

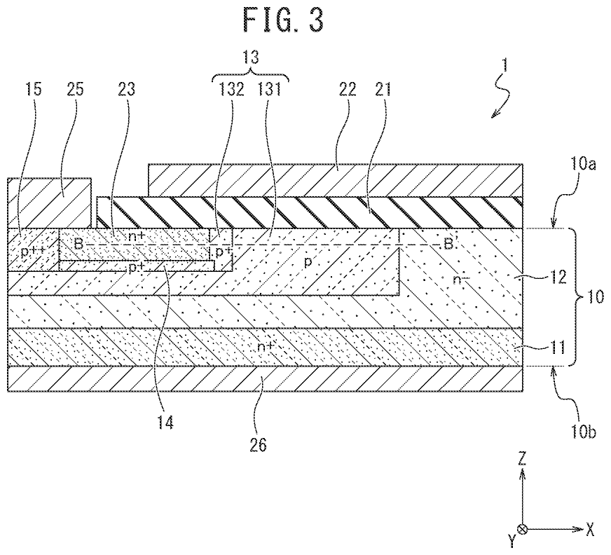

FIG. 1 is a plan view illustrating an example structure of a GaN (gallium nitride) semiconductor device 100 according to a first embodiment of the present disclosure (an example of the “nitride semiconductor device” of the present disclosure). In FIG. 1, illustrations of a gate insulator film 21, a gate electrode 22, and a source electrode 25 are omitted in order to show impurity diffused layers on the front surface 10a of the GaN substrate 10. FIG. 2 is a cross-sectional diagram illustrating an example structure of the GaN semiconductor device 100 according to the first embodiment of the present disclosure. FIG. 2 illustrates a cross section of the GaN substrate 10 illustrated in the plan view in FIG. 1 taken along line A-A′. FIG. 3 is an enlarged view of a portion of the cross-sectional diagram of FIG. 2.

The GaN semiconductor device 100 illustrated in FIG. 1 to FIG. 3 is a power device. As illustrated in FIG. 1 to FIG. 3, the GaN semiconductor device 100 includes a GaN substrate 10 having a front surface 10a and a rear surface 10b and a plurality of vertical MOSFETs (Metal Oxide Semiconductor Field Effect Transistor) 1 formed in the GaN substrate 10.

The GaN substrate 10 is an example of the “gallium nitride layer” of the present disclosure. The front surface 10a of the GaN substrate 10 is an example of the “first principal face” of the present disclosure, and the rear surface 10b located on opposite side of the front surface 10a is an example of the “second principal face” of the present disclosure. The vertical MOSFET 1 is an example of the “field effect transistor” of the present disclosure. For example, the plurality of vertical MOSFETs 1 is iteratively formed in one direction (e.g., the X-axis direction). A single vertical MOSFET 1 is a structural unit for iteration, and the structural units are arranged side by side in one direction.

As illustrated in FIG. 2 and FIG. 3, the GaN substrate 10 includes an n+ type GaN monocrystalline substrate 11 and an n− type GaN layer 12 formed on the GaN monocrystalline substrate 11.

The GaN monocrystalline substrate 11 is, for example, an n+ type c-plane GaN monocrystalline substrate. A type of n type impurities contained in the GaN monocrystalline substrate 11 is at least one of Si (silicon), O (oxygen), and Ge (germanium). As an example, the GaN monocrystalline substrate 11 contains Si as an n type impurity, and the impurity concentration of Si in the GaN monocrystalline substrate 11 is 5×10¹⁷ cm⁻³ or more.

The GaN monocrystalline substrate 11 may be a low-dislocation freestanding substrate having a dislocation density of 1×10⁷ cm⁻² or less. When the GaN monocrystalline substrate 11 is a low-dislocation freestanding substrate, the dislocation density of the GaN layer 12 formed on the GaN monocrystalline substrate 11 is also decreased. Employing a low-dislocation freestanding substrate also allows leakage current in a power device to be reduced even if a large-area power device is formed in the GaN substrate 10. Therefore, manufacturing equipment can manufacture power devices with a high non-defective product rate. Employing a low-dislocation freestanding substrate also prevents ion-implanted impurities from diffusing deeply along a dislocation in heat treatment.

The GaN layer 12 is a monocrystalline GaN layer that has been epitaxially grown on a surface of the GaN monocrystalline substrate 11. The GaN layer 12 is formed by doping an n type impurity in the course of epitaxial growth. An example of n type impurities is Si. The GaN layer 12 contains Si as an n type impurity at a concentration of, for example, 1×10¹⁵ cm⁻³ or more to 5×10¹⁶ cm⁻³ or less.

The vertical MOSFET 1 includes: a p type well region 13 (an example of the “p type region” of the present disclosure) formed in the GaN substrate 10 on a side of the front surface 10a (that is, a front surface of the n− type GaN layer 12); a p++ type contact region 15; and an n+ type source region 23 (an example of the “n type region” of the present disclosure). The vertical MOSFET 1 also includes: a gate insulator film 21 formed on the GaN substrate 10 on the side of the front surface 10a; a gate electrode 22 formed on the gate insulator film 21; a source electrode 25 (an example of the “first electrode” of the present disclosure) that is formed on the GaN substrate 10 on the side of the front surface 10a and in contact with the source region 23 and the contact region 15; a drain electrode 26 (an example of the “second electrode” of the present disclosure) that is formed on the GaN substrate 10 on a side of the rear surface 10b and in contact with the n+ type GaN monocrystalline substrate 11.

The vertical MOSFET 1 also includes a p+ type high-concentration region 14 located in the GaN substrate 10 between the source region 23 and the second principal face of the GaN substrate 10.

Example structures of the vertical MOSFET 1 will be described below in detail. On the side of the front surface 10a of the GaN substrate 10 (that is, a front surface of the n− type GaN layer 12), the p type well region 13, the n+ type source region 23, and the p+ type contact region 15 are formed.

The well region 13 is a p type layer formed after a p type impurity such as Mg (magnesium) is ion-implanted into the GaN substrate 10 on the side of the front surface 10a and activated by heat treatment. The well region 13 includes a p type first region 131 and a p+ type second region 132 that has a higher concentration of p type impurities than the first region 131. The first region 131 and the second region 132 are individually in contact with the gate insulator film 21. A surface of the first region 131 that is in contact with the gate insulator film 21 and its adjacent region and a surface of the second region 132 that is in contact with the gate insulator film 21 and its adjacent region make a channel region of the vertical MOSFET 1. The direction in which the first region 131 and the second region 132 are in contact with the gate insulator film 21 is the direction normal to the front surface 10a of the GaN substrate 10 (e.g., the Z-axis direction).

As illustrated in FIG. 1 to FIG. 3, the second region 132 lies between the first region 131 and the n+ type source region 23 in a direction parallel to an interface between the well region 13 and the gate insulator film 21 (e.g., the X-axis direction). In the X-axis direction, the second region 132 is in contact with each of the first region 131 and the source region 23. In the X-axis direction, the first region 131 is not directly connected to the source region 23 and it is connected to the source region 23 via the second region 132.

Although not illustrated, the second region 132 may lie between the first region 131 and the source region 23 not only in the X-axis direction but also in another direction that is parallel to the interface between the well region 13 and the gate insulator film 21 (e.g., the Y-axis direction). In other words, the second region 132 may lie between the first region 131 and the source region 23 without a gap in a horizontal direction parallel to the x-y plane that includes the X-axis direction and the Y-axis direction. In the horizontal direction, the first region 131 is not directly connected to the source region 23 and it may be connected to the source region 23 via the second region 132.

As described above, the second region 132 has a higher concentration of p type impurities than the first region 131. The concentration of p type impurities (e.g., the concentration of Mg) in the first region 131 is 1×10¹⁶ cm⁻³ or more but less than 1×10¹⁸ cm⁻³. The concentration of p type impurities (e.g., the concentration of Mg) in the second region 132 is 1×10¹⁸ cm⁻³ or more but less than 5×10¹⁸. The depth of the first region 131 from the front surface 10a is, for example, 500 nm or more. The depth of the second region 132 from the front surface 10a is, for example, 10 nm or more.

The source region 23 is an n+ type layer formed after an n type impurity such as Si, O, or Ge is ion-implanted into the GaN substrate 10 on the side of the front surface 10a and activated by heat treatment. The source region 23 contains as an n type impurity, for example, Si at a concentration of 1×10¹⁹ cm⁻³ or more to 5×10²⁰ cm⁻³ or less. The source region 23 is formed in the well region 13 located under the gate electrode 22 on both sides, and faces the front surface 10a of the GaN substrate 10 (that is, a front surface of the well region 13). The source region 23 is located inside of the well region 13 and in contact with the second region 132 of the well region 13. The depth of the source region 23 from the front surface 10a is, for example, 10 nm or more.

The contact region 15 is a p++ type layer formed after a p type impurity such as Mg is ion-implanted into the GaN substrate 10 on the side of the front surface 10a and activated by heat treatment. The contact region 15 has an even higher concentration of p type impurities than, for example, the p+ type high-concentration region 14. The contact region 15 preferably contains p type impurities (e.g., Mg) at a concentration of 5×10¹⁸ cm⁻³ or more to 1×10²¹ cm⁻³ or less, more preferably at a concentration of 1×10¹⁹ cm⁻³ or more to 2×10²⁰ cm⁻³ or less. The depth of the contact region 15 from the front surface 10a is, for example, 10 nm or more.

The contact region 15 faces the front surface 10a of the GaN substrate 10. The contact region 15 is located inside of the well region 13. The contact region 15 is connected to the well region 13 via the p+ type high-concentration region 14.

The p type well region 13 is connected to the source electrode 25 via the p+ type high-concentration region 14 and the p++ type contact region 15. Therefore, the potential of the well region 13 is fixedly set to the potential of the source electrode 25 (e.g., a reference potential such as the ground potential (GND)).

The gate insulator film 21 is, for example, an SiO₂ film. The gate insulator film 21 may be a single layer film that includes any one of an Al₂O₃ film, an SiON film, an AlSiO film, and an AlON film, or may be a laminated film that includes at least one of an SiO₂ film, an Al₂O₃ film, an SiON film, an AlSiO film, and an AlON film. The thickness of the gate insulator film 21 is, for example, 50 nm or more to 150 nm or less, and 100 nm as an example.

The gate electrode 22 is adjacent to the channel region across the gate insulator film 21. The gate electrode 22 is constructed from metal such as Al, Ti, Ni, or W or polysilicon into which impurities are doped. The gate electrode 22 may be constructed from silicide such as WSi or Nisi.

The source electrode 25 and the drain electrode 26 are constructed from, for example, an Al alloy or an Al—Si alloy, Ni, a Ni alloy, a Ti—Al alloy, or a Ni—Au alloy. The source electrode 25 may have a barrier metal layer on the border with the source region 23. The drain electrode 26 may have a barrier metal layer on the border with the n+ type GaN monocrystalline substrate 11. The barrier metal layer may be constructed from Ti (titanium).

In other words, the source electrode 25 and the drain electrode 26 may be constructed of lamination of a Ti layer and an Al layer or lamination of a Ti layer and an Al—Si alloy layer. The source electrode 25 may be an electrode that also serves as a source pad (not illustrated) or an electrode that is provided separately from the source pad. The drain electrode 26 may be an electrode that also serves as a drain pad (not illustrated) or an electrode that is provided separately from the drain pad.

The high-concentration region 14 is a p+ type layer, for example, which is formed after a p type impurity such as Mg is ion-implanted into the GaN substrate 10 on the side of the front surface 10a and activated by heat treatment. The p+ type high-concentration region 14 has a higher concentration of p type impurities (e.g., the concentration of Mg) than the first region 131 of the p type well region 13, and has a higher concentration of p type impurities (e.g., the concentration of Mg) than the second region 132. The concentration of p type impurities (e.g., the concentration of Mg) in the high-concentration region 14 is 5×10¹⁸ cm⁻³ or more but less than 1×10²⁰ cm⁻³. The high-concentration region 14 is located at, for example, 50 nm or more to 500 nm or less from the front surface 10a of the GaN substrate 10.

For example, as illustrated in FIG. 2 and FIG. 3, the high-concentration region 14 is continuously formed under the source region 23 and the contact region 15 and in contact with each of the source region 23 and the contact region 15 in the Z-axis direction. Under the high-concentration region 14, a portion of the p type well region 13 (e.g., a portion of the first region 131) is formed and the high-concentration region 14 is in contact with the portion of the first region 131 in the Z-axis direction. In addition, the high-concentration region 14 is also in contact with another portion of the p type well region 13 (e.g., the second region 132). For example, the high-concentration region 14 is in contact with the second region 132 in at least one of the X-axis direction and the Z-axis direction.

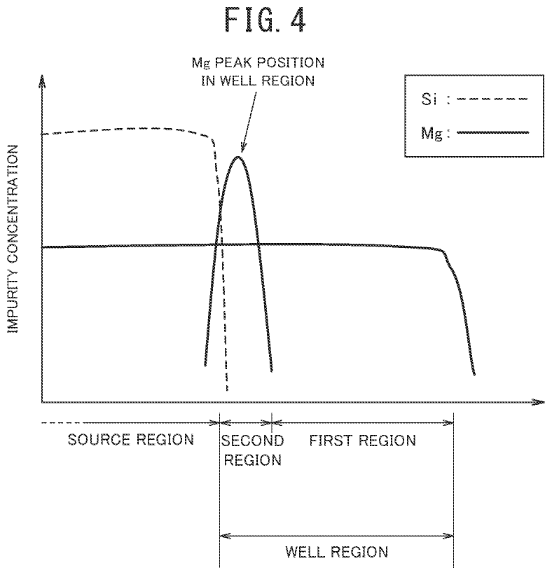

FIG. 4 is a graph illustrating a distribution of impurity concentration in the vertical MOSFET 1 illustrated in FIG. 3 along line B-B′. Line B-B′ is a line parallel to the front surface 10a of the GaN substrate 10 and it is also a line that passes through a region adjacent to a surface of the source region 23 and a region adjacent to a surface of the well region 13 including the channel region. The horizontal axis in FIG. 4 indicates a position in the X-axis direction while the vertical axis indicates the impurity concentration.

As illustrated in FIG. 4, in the well region 13, there is an Mg peak which is the highest concentration of p type impurities (e.g., the concentration of Mg) in the X-axis direction. This Mg peak is generated due to diffusion of Mg from an Mg diffusion source to be described later. The position of the Mg peak in the well region 13 exists in the second region 132.

### (Fabrication Method)

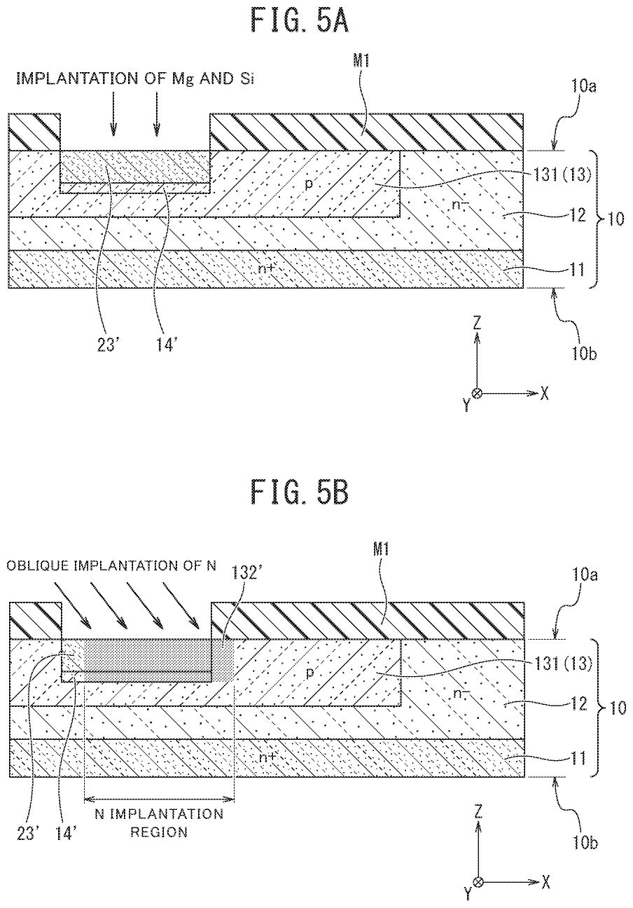

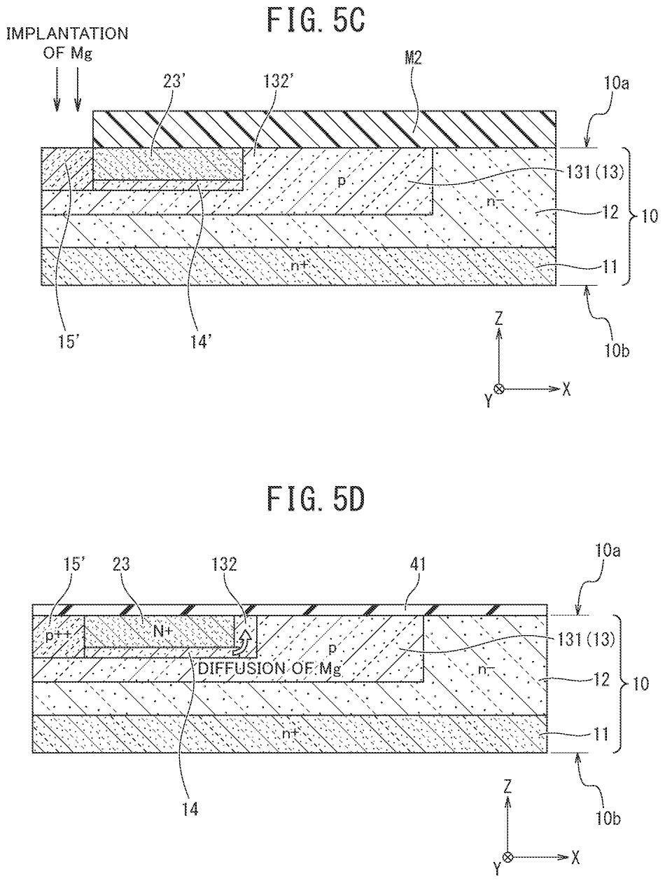

Next, a fabrication method of the GaN semiconductor device 100 that includes the vertical MOSFET 1 will be described. FIG. 5A to FIG. 5D are cross-sectional diagrams illustrating the fabrication method of the vertical MOSFET 1 according to the first embodiment of the present disclosure step by step. The GaN semiconductor device 100 is fabricated with various types of equipment such as a resist coating apparatus, exposure equipment, etching equipment, ion implantation equipment, heat treatment equipment, deposition equipment, and a CMP (Chemical Mechanical Polishing) apparatus. Hereinafter, such equipment and apparatuses are collectively referred to as manufacturing equipment.

In FIG. 5A, the manufacturing equipment causes the GaN layer 12 into which Si is doped to be epitaxially grown on the GaN monocrystalline substrate 11. Si is doped into the GaN layer 12 in the course of epitaxial growth. The thickness of the GaN layer 12 is, for example, 0.5 μm or more to 1 μm or less. The concentration of Si in the GaN layer 12 is, for example, 1×10¹⁵ cm⁻³ or more to 5×10¹⁶ cm⁻³ or less.

The manufacturing equipment then ion-implants a p type impurity into a region where the well region 13 is to be formed (herein after referred to as well-forming region) in the GaN layer 12. For example, the manufacturing equipment forms a mask (not illustrated) on the front surface 10a of the GaN substrate 10. The mask consists of photoresist, an SiO₂ film or an Al₂O₃ film. The mask has a shape that opens above the well-forming region and covers other regions from above. The manufacturing equipment ion-implants Mg into the GaN layer 12 over which the mask has been formed. With this ion implantation, the concentration of Mg in the well-forming region will be, for example, 1×10¹⁶ cm⁻³ or more but less than 1×10¹⁸ cm⁻³. After ion implantation, the manufacturing equipment removes the mask from the front surface 10a of the GaN substrate 10.

The manufacturing equipment then heat-treats the GaN substrate 10 and activates Mg that has been ion-implanted into the well-forming region. Accordingly, the p type well region 13 (the p type first region 131 in this case) is formed in the GaN layer 12.

The manufacturing equipment subsequently ion-implants an n type impurity into a region 23′ where the source region 23 is to be formed (herein after referred to as source-forming region) in the GaN layer 12. For example, the manufacturing equipment forms a mask M1 on the GaN layer 12. The mask M1 consists of photoresist, an SiO₂ film or an Al₂O₃ film. The mask M1 has a shape that opens above the source-forming region 23′ and covers other regions from above. The manufacturing equipment ion-implants Si into the GaN layer 12 over which the mask M1 has been formed. With this ion implantation, the concentration of Si in the source-forming region 23′ will be, for example, 1×10¹⁹ cm⁻³ or more to 5×10²⁰ cm⁻³ or less.

The manufacturing equipment then ion-implants Mg into the GaN layer 12 over which the mask M1 has been formed. With this ion implantation, Mg is implanted into a region 14′ where the p+ type high-concentration region 14 is to be formed (herein after referred to as high-concentration region forming region). In this fabrication method, the high-concentration region forming region 14′ is an example of the “high-concentration region” of the present disclosure. With this ion implantation, the concentration of Mg in the high-concentration region forming region 14′ will be, for example, 5×10¹⁸ cm⁻³ or more but less than 1×10²⁰ cm⁻³.

Subsequently, as illustrated in FIG. 5B, the manufacturing equipment ion-implants N (nitrogen) into the GaN layer 12 using the mask M1 as it is. In this case, Nis ion-implanted at an inclined angle relative to a direction normal to the front surface 10a of the GaN substrate 10 (e.g., the Z-axis direction). In other words, N is obliquely ion-implanted. The inclined angle relative to the Z-axis direction is, for example, 10° or more to 60° or less, and preferably 20° or more to 45° or less. A peak depth of N implantation from the front surface 10a of the GaN substrate 10 is preferably equal to or deeper than a peak depth of Mg implantation from the front surface 10a of the p+ type high-concentration region 14. N is obliquely ion-implanted in such a way that the concentration of implanted N at the peak depth of N implantation (hereinafter referred to as N implantation peak concentration) will be, for example, 5×10¹⁸ cm⁻³.

In this manner, N is introduced into each of the source-forming region 23′, the high-concentration region forming region 14′, and a region 132′ where the second region 132 is to be formed (herein after referred to as second region forming region). N is introduced into a region that includes an interface between the high-concentration region forming region 14′ that serves as an Mg diffusion source and the second region forming region 132′ that serves as an Mg diffusion destination at least.

The reason for ion-implanting N into the GaN layer 12 is to cause Mg serving as a p type impurity to be more diffusible by means of heat treatment to be described later. According to findings obtained by the present inventor, ion-implanting N into the GaN layer 12 causes Mg to be more diffusible. As the concentration of implanted N is higher, Mg will be more diffusible, and the concentration of Mg in an Mg diffused layer will be higher. The Mg diffused layer is a layer into which Mg is diffused by heat treatment. In the present embodiment, the second region 132 to be formed in a subsequent step corresponds to the Mg diffused layer.

According to findings obtained by the present inventor, ion-implanting N into the GaN layer 12 does almost nothing to diffusibility of Si that serves as an n type impurity. Even if the concentration of implanted N is increased, diffusibility of Si is not significantly different.

The order of performing ion implantation of Si, Mg, and N using the mask M1 is not limited to the one described above, and may be any desired order. In other words, ion implantation may be performed in the order of Mg, Si, and N, in the order of N, Si, and Mg, in the order of N, Mg, and Si, in the order of Si, N, and Mg, or in the order of Mg, N, and Si.

After ion implantation of Si, Mg, and N using the mask M1, the manufacturing equipment removes the mask M1 from the front surface 10a of the GaN substrate 10.

Subsequently, as illustrated in FIG. 5C, the manufacturing equipment ion-implants a p type impurity into a region 15′ where the contact region 15 is to be formed (herein after referred to as contact-forming region) in the GaN layer 12. For example, the manufacturing equipment forms a mask M2 on the GaN layer 12. The mask M2 consists of photoresist, an SiO₂ film or an Al₂O₃ film. The mask M2 has a shape that opens above the contact-forming region 15′ and covers other regions from above. The manufacturing equipment ion-implants Mg into the GaN layer 12 over which the mask M2 has been formed. With this ion implantation, the concentration of Mg in the contact-forming region 15′ will be higher than that in the high-concentration region forming region 14′, and will be, for example, 5×10¹⁸ cm⁻³ or more to 1×10²¹ cm⁻³ or less, more preferably will be 1×10¹⁹ cm⁻³ or more to 2×10²⁰ cm⁻³ or less. After ion implantation of Mg using the mask M2, the manufacturing equipment removes the mask M2 from the front surface 10a of the GaN substrate 10.

Subsequently, as illustrated in FIG. 5D, the manufacturing equipment forms a protective film 41 on the front surface 10a of the GaN substrate 10. The protective film 41 has a function of preventing N (nitrogen) atoms from being released from the GaN layer 12 during heat treatment to be described later. If N atoms are released from the GaN layer 12, N holes will be generated at positions from which the N atoms have been released. Since N holes may act as donor-type defects, exhibition of a p type property may be blocked. To prevent this, the manufacturing equipment covers the front surface 10a of the GaN substrate 10 with the protective film 41 in advance before performing heat treatment. The protective film 41 is, for example, an aluminum nitride (AlN) film, an SiO₂ film, a silicon nitride (SiN) film, or a laminated film including at least one thereof.

The manufacturing equipment then heat-treats the GaN substrate 10. With this heat treatment, both Si and Mg that have been ion-implanted into the GaN layer 12 are activated to form the n+ type source region 23, the p+ type high-concentration region 14, and the p++ type contact region 15. In addition, some of Mg contained in the high-concentration region forming region 14′ are diffused into the second region forming region 132′ and activated to form the p+ type second region 132 (Mg diffused layer). In this example, the high-concentration region forming region 14′ serves as the Mg diffusion source.

According to findings obtained by the present inventor, regarding the improved diffusibility of Mg by means of ion implantation of N, Mg will be effectively diffused into a p type region while Mg will be hardly diffused into an n type region. Therefore, even when diffusion of Mg from the high-concentration region forming region 14′ to adjacent regions is facilitated by ion implantation of N, Mg will be hardly diffused into the source-forming region 23′, and will be selectively diffused into the p type well region 13 into which N has been ion-implanted. Even if the region into which N has been implanted overlaps with the source-forming region 23′, it will not inhibit formation of the source region 23 that has a high concentration (n+ type).

At least some of crystal defects that have been generated in the GaN layer 12 due to ion implantation of Si, Mg, and N is recovered by this heat treatment. The maximum temperature in a chamber where the heat treatment is performed is, for example, between 1300° C. and 1500° C., inclusive. The pressure inside the chamber is not particularly limited. The heat treatment may be performed under very high pressure. The chamber is under an inert gas atmosphere, such as N₂ or Ar. The treating time under the aforementioned maximum temperature is five minutes or more to three hours or less. After the heat treatment, the manufacturing equipment removes the protective film 41 from the GaN layer 12.

The manufacturing equipment then forms the gate insulator film 21 (see FIG. 3) on the front surface 10a of the GaN substrate 10. Subsequently, the manufacturing equipment forms the gate electrode 22 (see FIG. 3) on the gate insulator film 21. The manufacturing equipment then forms the source electrode 25 over the n+ type source region 23 and the p++ type contact region 15. Around the same time as forming the source electrode 25, the manufacturing equipment forms the drain electrode 26 on the GaN substrate 10 on the side of the rear surface 10b. After the steps described above, the GaN semiconductor device 100 that includes the vertical MOSFET 1 having a vertical planar structure as illustrated in FIG. 1 to FIG. 3 is completed.

### Advantageous Effect of First Embodiment

As described above, the GaN semiconductor device 100 according to the first embodiment of the present disclosure includes the GaN substrate 10 having the front surface 10a and the rear surface 10b located on opposite side of the front surface 10a and the vertical MOSFET 1 formed in the GaN substrate 10. The vertical MOSFET 1 includes: the gate insulator film 21 formed on the GaN substrate 10 on the side of the front surface 10a; the p type well region 13 that is formed in the GaN substrate 10 and in contact with the gate insulator film 21; the n+ type source region 23 that is formed in the GaN substrate 10 and in contact with the well region 13 in a first direction (e.g., the X-axis direction) parallel to the interface between the well region 13 and the gate insulator film 21; and the source electrode 25 that is disposed on the side of the front surface 10a and in contact with the source region 23. The p type well region 13 includes the first region 131 that is in contact with the gate insulator film 21 and the second region 132 that is in contact with the gate insulator film 21 and lies in the X-axis direction between the first region 131 and the source region 23. The second region 132 has a higher concentration of p type impurities (e.g., the concentration of Mg) than the first region 131. For example, the first region 131 is a p type and the second region 132 being a Mg diffused layer is a p+ type.

Accordingly, the vertical MOSFET 1 has a structure in which the p type first region 131 and the p+ type second region 132 that has a higher concentration of p type impurities (e.g., the concentration of Mg) than the first region 131 exist in the channel region of the vertical MOSFET 1. An on-state current of the vertical MOSFET 1 flows from the side of the rear surface 10b of the GaN substrate 10 through the p type first region 131 and the p+ type second region 132 to the n+ type source region 23.

In this manner, a threshold voltage of the vertical MOSFET 1 can be controlled with the p+ type second region 132. In addition, mobility of the vertical MOSFET 1 can be secured with the p type first region 131. The threshold voltage and the mobility of the vertical MOSFET 1 can be individually controlled and secured with the impurity concentration (e.g., the concentration of Mg) in the first region 131 and the impurity concentration of the second region 132, and each of the threshold voltage and the mobility can be set to a high value. Therefore, the GaN semiconductor device 100 including the vertical MOSFET 1 that achieves a good balance between high threshold voltage and high mobility may be provided.

The fabrication method of the GaN semiconductor device 100 according to the first embodiment of the present disclosure includes: forming the p type well region 13 in the GaN substrate 10; forming, in the GaN substrate 10, the high-concentration region forming region 14′ (Mg diffusion source) in a region being in contact with the well region 13, the high-concentration region forming region 14′ having a higher concentration of p type impurities (e.g., Mg) than the well region 13; forming, by heat-treating the GaN substrate 10 to diffuse p type impurities from the high-concentration region forming region 14′ to the well region 13, the p+ type second region 132 that has a higher concentration of Mg than the first region 131 of the well region 13; forming the gate insulator film 21 on the GaN substrate 10 on the side of the front surface 10a, the gate insulator film being in contact with the p type first region 131 and the p+ type second region 132; forming the n+ type source region 23 in the GaN substrate 10 on the side of the front surface 10a opposite to the first region 131 across the second region 132; and forming the source electrode 25 that is in contact with the source region 23. In this manner, the vertical MOSFET 1 that achieves a good balance between high threshold voltage and high mobility may be fabricated.

In the fabrication method described above, the p+ type second region 132 is formed by means of diffusion of Mg from the high-concentration region forming region 14′ (Mg diffusion source). In the fabrication method, compared with a case in which the second region 132 is directly formed, for example, by ion implantation of Mg, limitation of the minimum dimension in processing the mask is not applicable, and the second region 132 can be easily formed more finely.

The fabrication method described above does not require a mask dedicated to forming the p+ type second region 132; therefore, addition of the mask formation step can be avoided. Therefore, compared with a case in which a dedicated mask is employed, increase of the manufacturing cost can be reduced.

In the fabrication method described above, N (nitrogen) is ion-implanted, before heat-treating the GaN substrate 10, into a region in the GaN layer 12, the region including the interface between the high-concentration region forming region 14′ that serves as an Mg diffusion source and the second region forming region 132′ that serves as an Mg diffusion destination. In this manner, p type impurities (e.g., Mg) can be efficiently diffused from the high-concentration region forming region 14′ to the second region forming region 132′.

### Variation Example of First Embodiment

In the first embodiment of the present disclosure, the contact region 15 may be omitted. Even in such a mode, the threshold voltage and the mobility of the vertical MOSFET 1 can be individually controlled and secured with the concentration of Mg in the first region 131 and the concentration of Mg in the second region 132, and each of the threshold voltage and the mobility can be set to a high value. Therefore, the vertical MOSFET 1 that achieves a good balance between high threshold voltage and high mobility may be achieved.

In the first embodiment of the present disclosure, forming the protective film 41 may be omitted. Even in this case, by performing the heat treatment, some of Mg contained in the high-concentration region forming region 14′ can be diffused into the second region forming region 132′ and activated to form the p+ type second region 132.

### Second Embodiment

In the first embodiment described above, a mode has been described in which the p+ type high-concentration region 14 is disposed only under the n+ type source region 23. However, embodiments of the present disclosure are not limited to such a mode. The high-concentration region 14 may extend outward from below the source region 23.

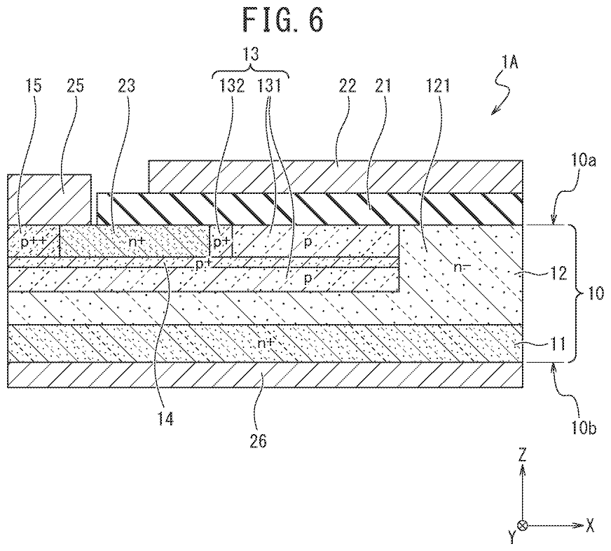

FIG. 6 is a cross-sectional diagram illustrating an example structure of a vertical MOSFET 1A according to a second embodiment of the present disclosure. As illustrated in FIG. 6, in the vertical MOSFET 1A according to the second embodiment, the p+ type high-concentration region 14 extends outward from below the source region 23 and is in contact with a JFET region 121. For example, a p-n interface between the p type first region 131 and the n− type JFET region 121 and a p-n interface between the p+ type high-concentration region 14 and the n− type JFET region 121 are exactly or nearly flush with each other.

In the second embodiment, the p type first region 131 and the p+ type second region 132 exist in a channel region of the vertical MOSFET 1A in the same manner as the first embodiment. Threshold voltage and mobility of the vertical MOSFET 1A can be individually controlled and secured with the concentration of Mg in the first region 131 and the concentration of Mg in the second region 132, and each of the threshold voltage and the mobility can be set to a high value. Therefore, the vertical MOSFET 1A that achieves a good balance between high threshold voltage and high mobility may be achieved.

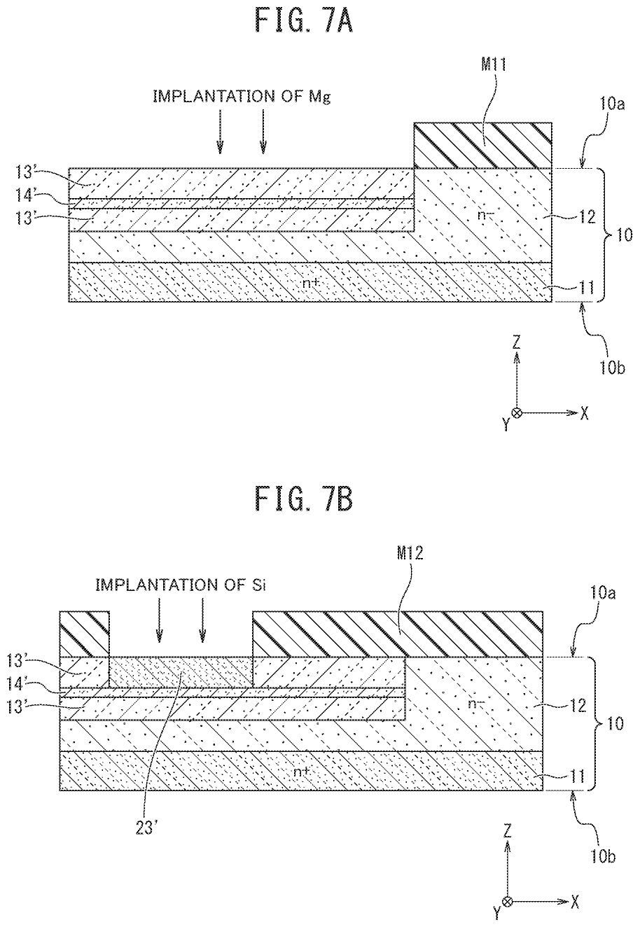

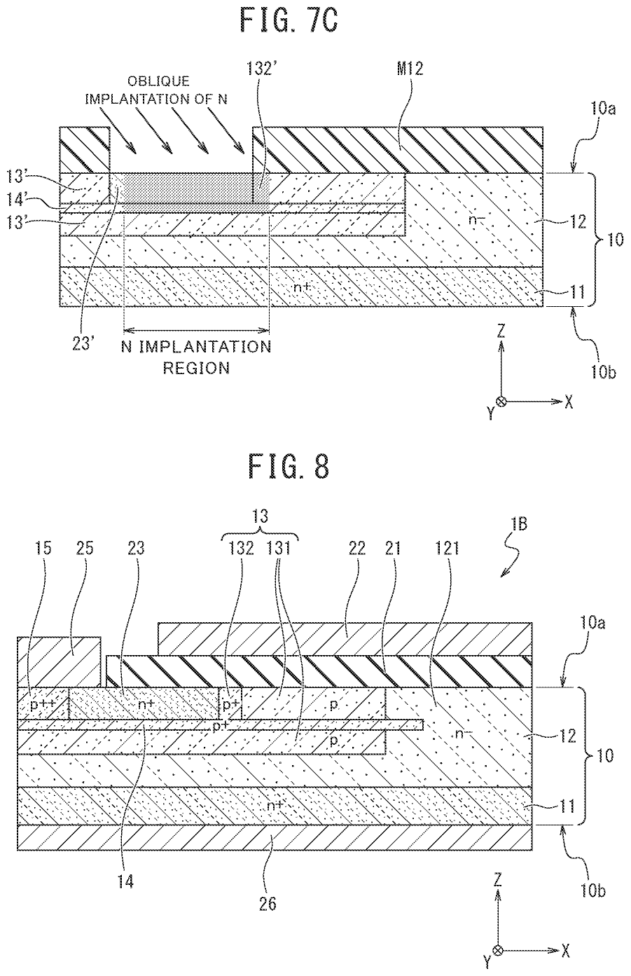

FIG. 7A to FIG. 7C are cross-sectional diagrams illustrating a fabrication method of the vertical MOSFET 1A according to the second embodiment of the present disclosure step by step. FIG. 7A illustrates ion-implanting Mg as a p type impurity into the well-forming region 13′ and the high-concentration region forming region 14′. As illustrated in FIG. 7A, the manufacturing equipment forms a mask M11 on the front surface 10a of the GaN substrate 10. The mask M11 has a shape that opens above the well-forming region 13′ and covers other regions from above. The mask M11 consists of photoresist, an SiO₂ film or an Al₂O₃ film.

The manufacturing equipment ion-implants Mg into the GaN layer 12 over which the mask M11 has been formed. With this ion implantation, Mg is introduced into the well-forming region 13′. The manufacturing equipment ion-implants Mg into the high-concentration region forming region 14′ around the same time as the ion implantation of Mg into the well-forming region 13′. The mask M11 is also used in the ion implantation of Mg into the high-concentration region forming region 14′.

The manufacturing equipment can introduce Mg into each of the well-forming region 13′ and the high-concentration region forming region 14′ by using the same mask M11 and ion-implanting Mg into the GaN layer 12 under different ion implantation conditions for each region (different dose amount of Mg and different energy for implanting Mg for each region). Ion implantation of Mg into the well-forming region 13′ and ion implantation of Mg into the high-concentration region forming region 14′ are, for example, sequentially performed in the same chamber.

After ion implantation of Mg using the mask M11, the manufacturing equipment removes the mask M11 from the front surface 10a of the GaN substrate 10.

Subsequently, as illustrated in FIG. 7B, the manufacturing equipment forms a mask M12 on the front surface 10a of the GaN substrate 10. The mask M12 has a shape that opens above the well-forming region 13′ and covers other regions from above. The mask M12 consists of photoresist, an SiO₂ film or an Al₂O₃ film. The mask M12 has a shape that opens above the source-forming region 23′ and covers other regions from above. The manufacturing equipment ion-implants Si into the GaN layer 12 over which the mask M12 has been formed. With this ion implantation, Si is introduced into the source-forming region 23′.

Subsequently, as illustrated in FIG. 7C, the manufacturing equipment ion-implants N (nitrogen) into the GaN layer 12 using the mask M12 as it is. The manufacturing equipment obliquely ion-implants N (nitrogen) in the same manner as the first embodiment. In this manner, N is introduced into each of the source-forming region 23′, the high-concentration region forming region 14′, and the second region forming region 132′. After ion implantation of N using the mask M12, the manufacturing equipment removes the mask M12 from the front surface 10a of the GaN substrate 10.

The manufacturing equipment then ion-implants Mg into the contact-forming region 15′ using a mask (not illustrated) in the same manner as the first embodiment. After ion implantation, the manufacturing equipment removes the mask.

Subsequently, the manufacturing equipment forms the protective film 41 (see FIG. 5D) on the front surface 10a of the GaN substrate 10. The manufacturing equipment then heat-treats the GaN substrate 10. With this heat treatment, both Si and Mg that have been ion-implanted into the GaN layer 12 are activated to form the p type first region 131, the n+ type source region 23, the p+ type high-concentration region 14, and the p++ type contact region 15, which are illustrated in FIG. 6. In addition, some of Mg contained in the high-concentration region forming region 14′ are diffused into the second region forming region 132′ and activated to form the p+ type second region 132.

Steps that follow are the same as those in the first embodiment. The manufacturing equipment forms the gate insulator film 21 (see FIG. 6) on the front surface 10a of the GaN substrate 10. Subsequently, the manufacturing equipment forms the gate electrode 22 (see FIG. 6) on the gate insulator film 21. The manufacturing equipment then forms the source electrode 25 over the n+ type source region 23 and the p++ type contact region 15. Around the same time as forming the source electrode 25, the manufacturing equipment forms the drain electrode 26 on the GaN substrate 10 on the side of the rear surface 10b.

After the steps described above, the GaN semiconductor device 100 that includes the vertical MOSFET 1A having a vertical planar structure as illustrated in FIG. 6 is completed. According to the fabrication method described above, the vertical MOSFET 1A that achieves a good balance between high threshold voltage and high mobility may be fabricated.

### Variation Example of Second Embodiment

FIG. 8 is a cross-sectional diagram illustrating an example structure of a vertical MOSFET 1B according to a variation example of the second embodiment of the present disclosure. As illustrated in FIG. 8, in the vertical MOSFET 1B according to the variation example of the second embodiment, the p-n interface between the p type first region 131 and the n− type JFET region 121 and the p-n interface between the p+ type high-concentration region 14 and the n− type JFET region 121 are not flush with each other. The p+ type high-concentration region 14 protrudes into the n− type JFET region 121.

Even in such a mode, the p type first region 131 and the p+ type second region 132 exist in a channel region of the vertical MOSFET 1B in the same manner as the second embodiment described above. Threshold voltage and mobility of the vertical MOSFET 1B can be individually controlled and secured with the concentration of Mg in the first region 131 and the concentration of Mg in the second region 132, and each of the threshold voltage and the mobility can be set to a high value. Therefore, the vertical MOSFET 1B that achieves a good balance between high threshold voltage and high mobility may be achieved.

### Third Embodiment

In the first and second embodiments described above, modes have been described in which the well region 13 is connected to the source electrode 25 via the p++ type contact region 15. However, embodiments of the present disclosure are not limited to such modes. The well region 13 may be connected to the source electrode 25, for example, via the p+ type second region 132.

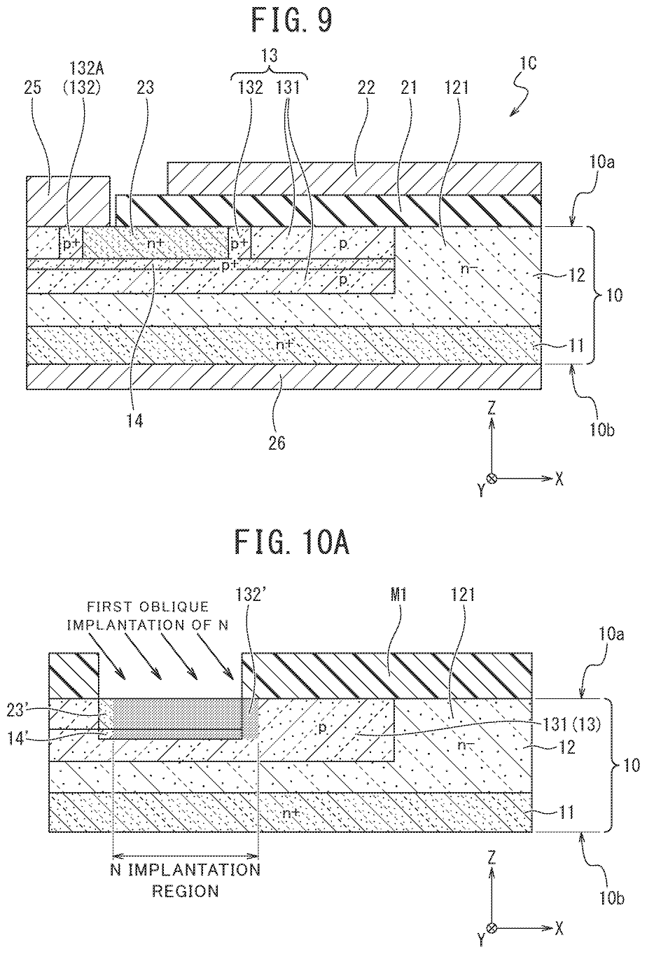

FIG. 9 is a cross-sectional diagram illustrating an example structure of a vertical MOSFET 1C according to a third embodiment of the present disclosure. As illustrated in FIG. 9, in the vertical MOSFET 1C according to the third embodiment, the p+ type second regions 132 are disposed on both sides in the X-axis direction of the source region 23. Alternatively, the p+ type second regions 132 may be disposed along an outer perimeter of the source region 23.

A portion of the p+ type second region 132 (hereinafter referred to as the second region 132A) is located between the p+ type high-concentration region 14 and the n+ type source electrode 25. The well region 13 is connected to the source electrode 25 via the high-concentration region 14 and the second region 132A. Therefore, the potential of the well region 13 is fixedly set to the potential of the source electrode 25 (e.g., a reference potential such as the ground potential (GND)).

Even in such a mode, the p type first region 131 and the p+ type second region 132 exist in a channel region of the vertical MOSFET 1C in the same manner as the first and the second embodiments described above. Threshold voltage and mobility of the vertical MOSFET 1C can be individually controlled and secured with the concentration of Mg in the first region 131 and the concentration of Mg in the second region 132, and each of the threshold voltage and the mobility can be set to a high value. Therefore, the vertical MOSFET 1C that achieves a good balance between high threshold voltage and high mobility may be achieved.

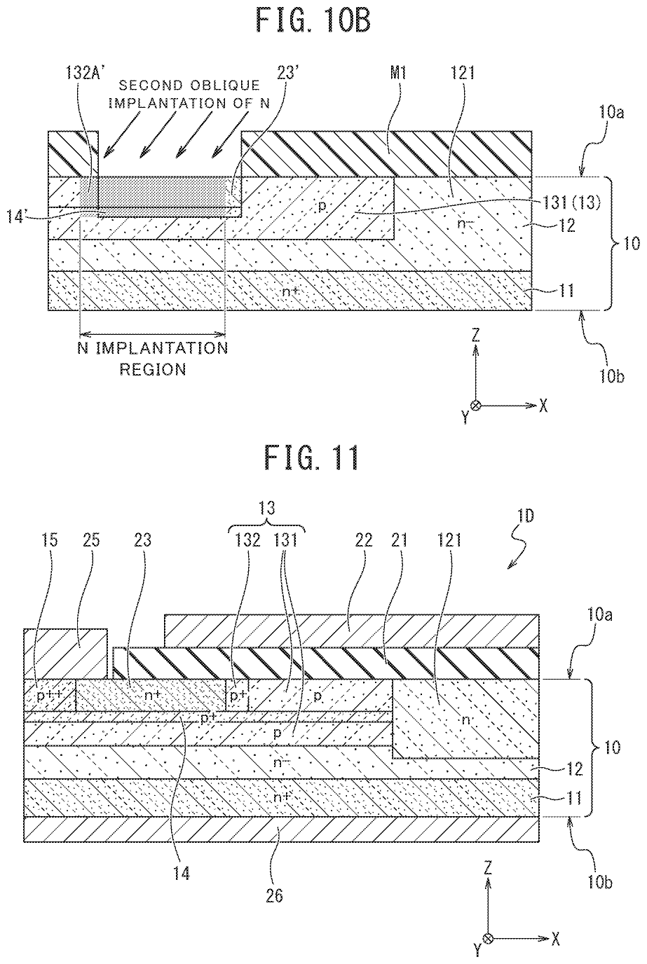

FIGS. 10A and 10B are cross-sectional diagrams each illustrating a fabrication method of the vertical MOSFET 1C according to the third embodiment of the present disclosure step by step. In FIG. 10A, fabrication steps until forming the mask M12 are the same as those in the second embodiment that have been described with reference to FIG. 7A to FIG. 7C.

As illustrated in FIG. 10A, the manufacturing equipment obliquely ion-implants N into the second region forming region 132′ located on the side of the JFET region 121 using the mask M12. Subsequently, as illustrated in FIG. 10B, the manufacturing equipment obliquely ion-implants N into the second region forming region 132A′ located on opposite side of the JFET region 121 across the source-forming region 23 using the mask M12 as it is.

For example, when an inclination angle of the oblique ion implantation (hereinafter, referred to as first oblique implantation of N), which is illustrated in FIG. 10A, relative to the Z-axis direction is θ°, an inclination angle of the oblique ion implantation (hereinafter, referred to as second oblique implantation of N), which is illustrated in FIG. 10B, relative to the Z-axis direction is −θ°. The first oblique implantation of N and the second oblique implantation of N are, for example, sequentially performed in the same chamber. In this manner, the manufacturing equipment introduces N into each of the second region forming regions 132′ and 132A′, that are located on both sides of the source-forming region 23′. After introduction of N, the manufacturing equipment removes the mask M12.

Subsequently, the manufacturing equipment forms the protective film 41 (see FIG. 5D) on the front surface 10a of the GaN substrate 10. The manufacturing equipment then heat-treats the GaN substrate 10. With this heat treatment, both Si and Mg that have been ion-implanted into the GaN layer 12 are activated to form the n+ type source region 23 and the p+ type high-concentration region 14, which are illustrated in FIG. 9. In addition, some of Mg contained in the high-concentration region forming region 14′ are diffused into the second region forming region 132′ and activated to form the p+ type second regions 132 and 132A.

Steps that follow are the same as those in the first embodiment. The manufacturing equipment sequentially forms the gate insulator film 21, the gate electrode 22, the source electrode 25, and the drain electrode 26, which are illustrated in FIG. 9. After the steps described above, the GaN semiconductor device 100 that includes the vertical MOSFET 1C having a vertical planar structure as illustrated in FIG. 9 is completed.

According to the fabrication method described above, the vertical MOSFET 1C that achieves a good balance between high threshold voltage and high mobility may be fabricated. In addition, according to the fabrication method described above, forming the contact region 15 may be omitted; therefore, the fabrication steps may be reduced and the manufacturing cost may be reduced.

### Fourth Embodiment

In the first to the third embodiments described above, modes have been described in which the p type well region 13 and the p+ type high-concentration region 14 are formed by ion implantation. However, in embodiments of the present disclosure, formation methods of the well region 13 and the high-concentration region 14 are not limited by such modes. The well region 13 and the high-concentration region 14 may be formed, for example, by means of an epitaxial method.

In the GaN layer 12, the JFET region 121 may have a higher concentration of n type impurities than other regions. Methods for increasing the concentration of n type impurities in the JFET region 121 higher than those in other regions include ion-implanting n type impurities (e.g., Si) into the JFET region 121 and forming the JFET region 121 separately from other regions using a selective epitaxial growth process.

FIG. 11 is a cross-sectional diagram illustrating an example structure of a vertical MOSFET 1D according to a fourth embodiment of the present disclosure. In the vertical MOSFET 1D illustrated in FIG. 11, each of the p type well region 13 and the p+ type high-concentration region 14 is formed using an epitaxial growth process. The JFET region 121 is, for example, an n type. The JFET region 121 is formed by ion implantation in such a way that the concentration of n type impurities in JFET region 121 is higher than those in other regions in the GaN layer 12.

Even in such a mode, the p type first region 131 and the p+ type second region 132 exist in a channel region of the vertical MOSFET 1D in the same manner as the first to the third embodiments described above. Threshold voltage and mobility of the vertical MOSFET 1D can be individually controlled and secured with the concentration of Mg in the first region 131 and the concentration of Mg in the second region 132, and each of the threshold voltage and the mobility can be set to a high value. Therefore, the vertical MOSFET 1D that achieves a good balance between high threshold voltage and high mobility may be achieved.

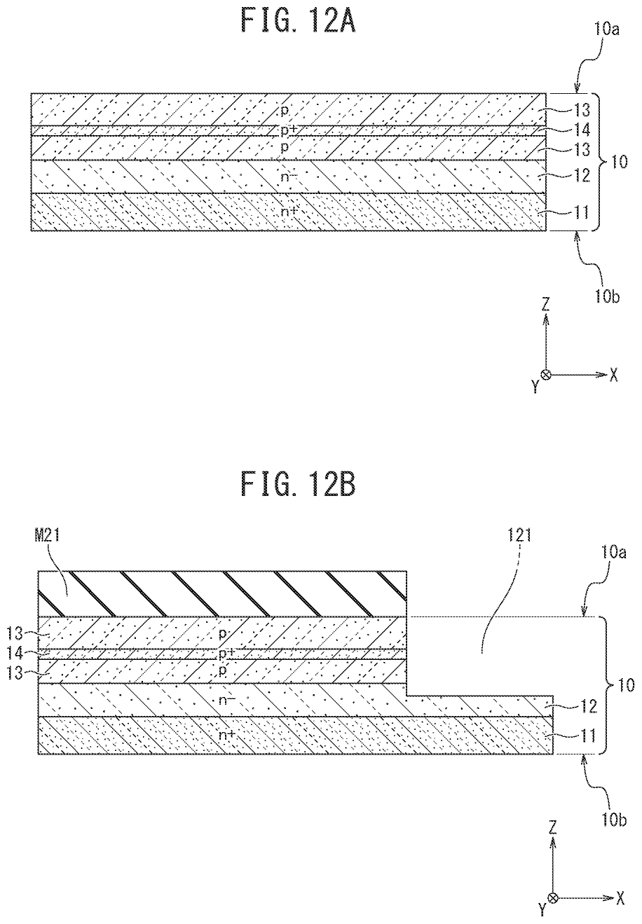

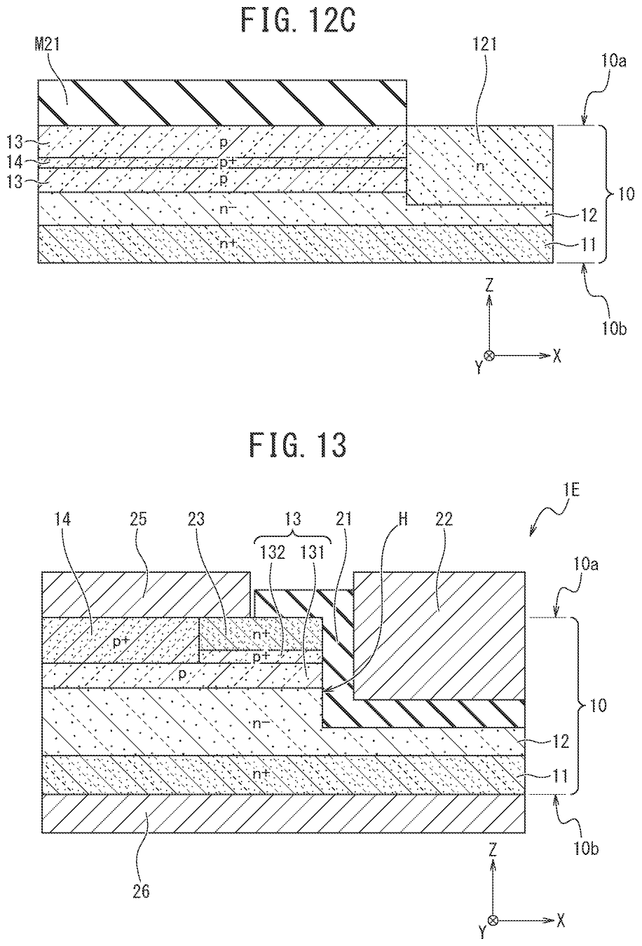

FIG. 12A to FIG. 12C are cross-sectional diagrams illustrating a fabrication method of the vertical MOSFET 1D according to the fourth embodiment of the present disclosure step by step. As illustrated in FIG. 12A, the manufacturing equipment causes a lower layer of the p type well region 13, the p+ type high-concentration region 14, and an upper layer of the p type well region 13 to be epitaxially grown above the n− type GaN layer 12 in this order.

Subsequently, as illustrated in FIG. 12B, the manufacturing equipment forms a mask M21 on the upper layer of the well region 13. The mask M21 is made of, for example, an SiO₂ film. The mask M21 has a shape that opens above the JFET region 121 and covers other regions from above. The manufacturing equipment etches the GaN layer 12 over which the mask M21 is formed and removes the JFET region 121.

Subsequently, as illustrated in FIG. 12C, the manufacturing equipment causes the JFET region 121 consisting of an n type GaN layer to be grown on the n− type GaN layer 12 that is not covered by the mask M21 by means of a selective epitaxial growth process. The manufacturing equipment then removes the mask M21.

Steps that follow are the same as, for example, those in the first embodiment illustrated in FIG. 5A to FIG. 5D. The manufacturing equipment ion-implants N (nitrogen) into the GaN layer 12, heat-treats the GaN layer 12, and forms the p+ type second region 132 (see FIG. 11). In this heat treatment, the p+ type high-concentration region 14 serves as the Mg diffusion source. The manufacturing equipment then sequentially forms the gate insulator film 21, the gate electrode 22, the source electrode 25, and the drain electrode 26, which are illustrated in FIG. 11.

After the steps described above, the GaN semiconductor device 100 that includes the vertical MOSFET 1D having a vertical planar structure as illustrated in FIG. 11 is completed. According to the fabrication method described above, the vertical MOSFET 1D that achieves a good balance between high threshold voltage and high mobility may be fabricated.

### Variation Example of Fourth Embodiment

Although, in the fabrication method described above, it has been described that the n type JFET region 121 is formed by means of a selective epitaxial growth process, the n type JFET region 121 may be formed by ion implantation. For example, the n type JFET region 121 may be formed not by etching the GaN layer 12 over which the mask M21 is formed, but by ion-implanting n type impurities (e.g., Si) to form the n type JFET region 121 on the GaN layer 12 that is not covered by the mask M21.

Even with this fabrication method, the vertical MOSFET 1D as illustrated in FIG. 11 may be formed. Note that when the n type JFET region 121 is formed by ion implantation, photoresist may be used for the mask M21.

### Fifth Embodiment

In the first to the fourth embodiments described above, it has been described that the vertical MOSFET included in the GaN semiconductor device 100 has a vertical planar structure. However, the structure of the vertical MOSFET included in the GaN semiconductor device 100 is not limited to a vertical planar structure, and it may be a trench gate structure.

FIG. 13 is a cross-sectional diagram illustrating an example structure of a vertical MOSFET 1E according to a fifth embodiment of the present disclosure. As illustrated in FIG. 13, the vertical MOSFET 1E according to the fifth embodiment has a trench gate structure. Specifically, the vertical MOSFET 1E includes a trench H formed in the GaN substrate 10. The trench H opens on the side of the front surface 10a of the GaN substrate 10. The trench H is formed more deeply than the p type well region 13 and the bottom of the trench H reaches the n− type GaN layer 12.

Inside the trench H, the gate insulator film 21 and the gate electrode 22 are disposed. The gate insulator film 21 covers a side surface and a bottom surface on the inner side of the trench H. The gate electrode 22 is buried in the trench H with the gate insulator film 21 in between. In the vertical MOSFET 1E, a region in the p type well region 13 that faces the gate electrode 22 across the gate insulator film 21 formed on the side face on the inner side of the trench H is a channel region.

In the vertical MOSFET 1E, the p type well region 13 includes the p type first region 131 and the p+ type second region 132. The p type first region 131 and the p+ type second region 132 are individually in contact with the gate insulator film 21 in the X-axis direction. Alternatively, the p type first region 131 and the p+ type second region 132 may be individually in contact with the gate insulator film 21 in a horizontal direction parallel to the x-y plane that includes the X-axis direction and the Y-axis direction.

In the fifth embodiment, the first direction parallel to an interface between the p type well region 13 and the gate insulator film 21 is, for example, the Z-axis direction. The p+ type second region 132 lies in the Z-axis direction between the p type first region 131 and the n+ type source region 23.

Even in such a mode, the p type first region 131 and the p+ type second region 132 exist in a channel region of the vertical MOSFET 1E in the same manner as the first to the fourth embodiments described above. Threshold voltage and mobility of the vertical MOSFET 1E can be individually controlled and secured with the concentration of Mg in the first region 131 and the concentration of Mg in the second region 132, and each of the threshold voltage and the mobility can be set to a high value. Therefore, the vertical MOSFET 1E that achieves a good balance between high threshold voltage and high mobility may be achieved.

Between the well region 13 and the source electrode 25, the high-concentration region 14 is located. For example, in the Z-axis direction, the source electrode 25 is in contact with the high-concentration region 14 while the high-concentration region is in contact with the well region 13. Therefore, the well region 13 is connected to the source electrode 25 via the high-concentration region 14. The potential of the well region 13 is fixedly set to the potential of the source electrode 25 (e.g., a reference potential such as the ground potential (GND)) via the high-concentration region 14.

In the fifth embodiment, the high-concentration region 14 serves not only as the Mg diffusion source for the second region forming region 132′ but also as an alternative for the p++ type contact region 15 as illustrated in FIG. 3 or the like. The high-concentration region 14 serves as the Mg diffusion source and a p type region for the source/contact region.

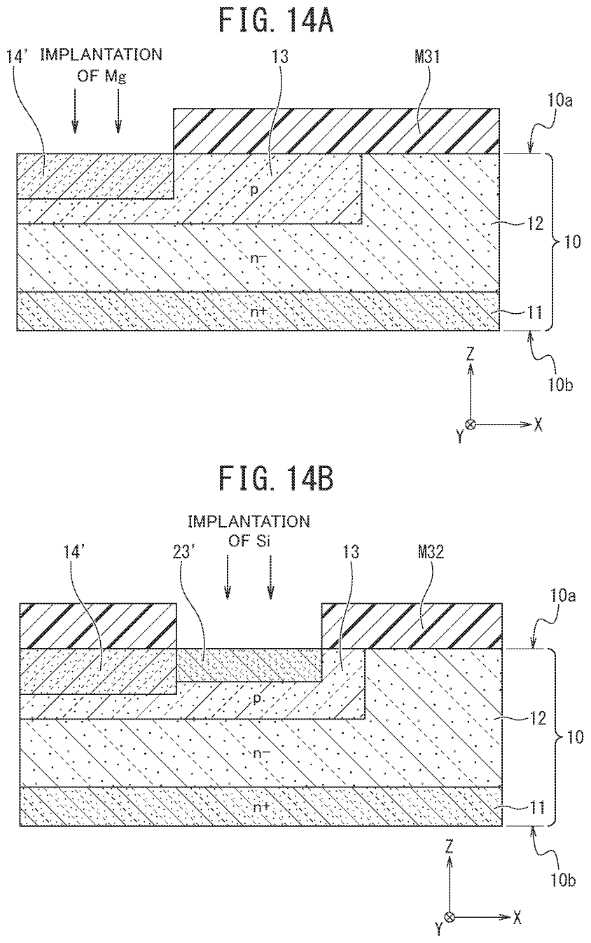

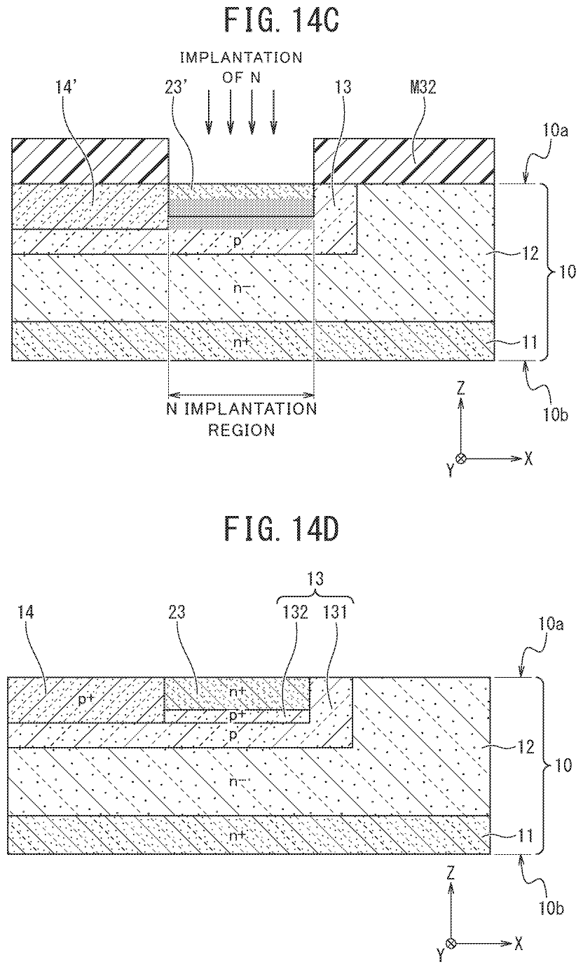

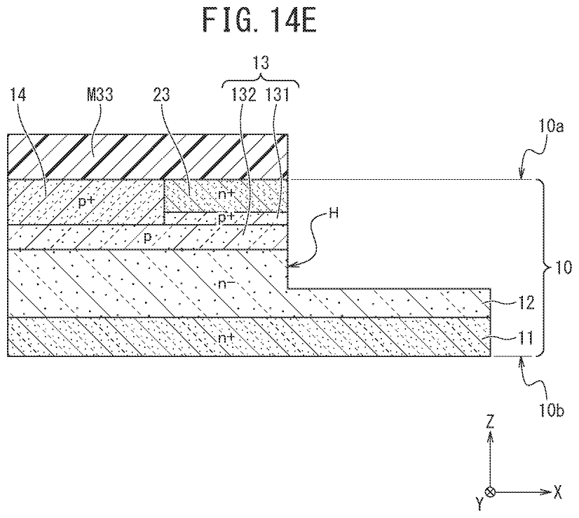

FIG. 14A to FIG. 14E are cross-sectional diagrams illustrating a fabrication method of the vertical MOSFET 1E according to the fifth embodiment of the present disclosure step by step. FIG. 14A illustrates ion-implanting Mg as a p type impurity into the high-concentration region forming region 14′. As illustrated in FIG. 14A, the manufacturing equipment forms a mask M31 on the front surface 10a of the GaN substrate 10. The mask M31 has a shape that opens above the high-concentration region forming region 14′ and covers other regions from above. The mask M31 consists of photoresist, an SiO₂ film or an Al₂O₃ film.

The manufacturing equipment ion-implants Mg into the GaN layer 12 over which the mask M31 has been formed. With this ion implantation, Mg is introduced into the high-concentration region forming region 14′. After ion implantation of Mg using the mask M31, the manufacturing equipment removes the mask M31 from the front surface 10a of the GaN substrate 10.

Subsequently, as illustrated in FIG. 14B, the manufacturing equipment forms a mask M32 on the front surface 10a of the GaN substrate 10. The mask M32 has a shape that opens above the source-forming region 23′ and covers other regions from above. The manufacturing equipment ion-implants Si into the GaN layer 12 over which the mask M32 has been formed. With this ion implantation, Si is introduced into the source-forming region 23′.

Subsequently, as illustrated in FIG. 14C, the manufacturing equipment ion-implants N (nitrogen) into the GaN layer 12 using the mask M32 as it is. In this manner, N is introduced into each of the source-forming region 23′ and the p type well region 13 located under the source-forming region 23′. After ion implantation of Si and N using the mask M32, the manufacturing equipment removes the mask M32 from the front surface 10a of the GaN substrate 10.

Subsequently, the manufacturing equipment forms the protective film 41 on the front surface 10a of the GaN substrate 10. The manufacturing equipment then heat-treats the GaN substrate 10. With this heat treatment, both Mg and Si that have been ion-implanted into the GaN layer 12 are activated to form the p+ type high-concentration region 14 and the n+ type source region 23, which are illustrated in FIG. 14D. In addition, some of Mg contained in the high-concentration region forming region 14′ are diffused into the second region forming region 132′ into which N has been ion-implanted and activated to form the p+ type second region 132. In this example, Mg diffuses from the high-concentration region forming region 14′ in the X-axis direction (or a horizontal direction).

Subsequently, as illustrated in FIG. 14E, the manufacturing equipment forms a mask M33 on the front surface 10a of the GaN substrate 10. The mask M33 has a shape that opens above a region in which the trench H is to be formed and covers other regions from above. The manufacturing equipment etches the GaN layer 12 over which the mask M33 is formed and forms the trench H. After forming the trench H, the manufacturing equipment removes the mask M33 from the front surface 10a of the GaN substrate 10. The manufacturing equipment then sequentially forms the gate insulator film 21, the gate electrode 22, the source electrode 25, and the drain electrode 26, which are illustrated in FIG. 13.

After the steps described above, the GaN semiconductor device 100 that includes the vertical MOSFET 1E having a trench gate structure as illustrated in FIG. 13 is completed. According to the fabrication method described above, the vertical MOSFET 1E that achieves a good balance between high threshold voltage and high mobility may be fabricated.

### Other Embodiments

As described above, the present disclosure has been described with embodiments and variation examples. However, the description and drawings that constitute part of the present disclosure should not be construed as limiting the present disclosure. Those skilled in the art would conceive various alternative embodiments and variation examples from the present disclosure. The present disclosure obviously encompasses such various embodiments and the like that are not described herein.

For example, in the first to the fifth embodiments described above, modes have been described in which the p+ type second region 132 is in contact with the n+ type source region 23. However, in embodiments of the present disclosure, the second region 132 does not necessarily have to be in contact with the source region 23. The p type first region 131 may lie between the p+ type second region 132 and the n+ type source region 23.

A plurality of p+ type second regions 132 may be disposed along the X-axis direction. Of the plurality of second regions 132, the p type first region 131 may lie between two second regions 132 adjacent in the X-axis direction.

The p+ type second region 132 may be formed by ion implantation of Mg instead of diffusion of Mg generated by heat treatment from the high-concentration region forming region 14′ or from the high-concentration region 14. In this case, the high-concentration region forming region 14′ or the high-concentration region 14 serving as the Mg diffusion source need not exist.

Thus, without departing from the gist of the embodiments and variation examples described above, at least one of omission, substitution, and modification of various components may be made. In addition, advantageous effects described in the present description are merely illustrative and not limiting, so there may be other advantageous effects. The technical scope of the present disclosure shall be defined only by matters specifying the claimed invention, which are deemed valid from the description above.

Configurations described below may be taken for the present disclosure:

(1)

A nitride semiconductor device, including:
a gallium nitride layer having a first principal face and a second principal face, the second principal face being located on opposite side of the first principal face; and
a field effect transistor formed in the gallium nitride layer,
wherein the field effect transistor includes:
a gate insulator film formed on the gallium nitride layer on a side of the first principal face;
a p type region formed in the gallium nitride layer, the p type region being in contact with the gate insulator film;
an n type region formed in the gallium nitride layer, the n type region being in contact with the p type region in a first direction parallel to an interface between the p type region and the gate insulator film; and
a first electrode disposed on the side of the first principal face, the first electrode being in contact with the n type region,
wherein the p type region includes:
a first region being in contact with the gate insulator film; and
a second region being in contact with the gate insulator film and lying in the first direction between the first region and the n type region,
wherein the second region has a higher concentration of p type impurities than the first region.
   (2)

The nitride semiconductor device according to (1), wherein the first region and the second region exist in a channel region of the field effect transistor.

(3)

The nitride semiconductor device according to (1) or (2), wherein an on-state current of the field effect transistor flows from a side of the second principal face of the gallium nitride layer through the first region and the second region to the n type region.

(4)

The nitride semiconductor device according to any one of (1) to (3),
wherein a peak position exists in the p type region, the peak position being a position where a concentration of p type impurities is the highest in the first direction,
wherein the peak position exists in the second region.
   (5)

The nitride semiconductor device according to any one of (1) to (4), wherein the second region is in contact with the n type region.

(6)

The nitride semiconductor device according to any one of (1) to (5),
wherein the field effect transistor further includes:
a p type high-concentration region formed in the gallium nitride layer, the high-concentration region being located between the n type region and the second principal face,
wherein the high-concentration region has a higher concentration of p type impurities than the first region and is in contact with the second region.
   (7)

The nitride semiconductor device according to (6), wherein the high-concentration region has a higher concentration of p type impurities than the second region.

(8)

The nitride semiconductor device according to (6) or (7), wherein the high-concentration region is in contact with the n type region.

(9)

The nitride semiconductor device according to any one of (6) to (8), wherein the high-concentration region is in contact with the first electrode.

(10)

The nitride semiconductor device according to any one of (6) to (9), wherein the high-concentration region is in contact with the first region.

(11)

The nitride semiconductor device according to any one of (6) to (10),
wherein the concentration of p type impurities in the high-concentration region is 5×10¹⁸ cm⁻³ or more but less than 1×10²⁰ cm⁻³,
wherein the concentration of p type impurities in the second region is 1×10¹⁸ cm⁻³ or more but less than 5×10¹⁸ cm⁻³, and
wherein the concentration of p type impurities in the first region is 1×10¹⁶ cm⁻³ or more but less than 1×10¹⁸ cm⁻³.
   (12)

The nitride semiconductor device according to any one of (1) to (11), wherein the field effect transistor further includes:
a second electrode formed on the side of the second principal face.
   (13)

A fabrication method of a nitride semiconductor device, including:
forming a p type region in a gallium nitride layer;
forming, in the gallium nitride layer, a high-concentration region in a region being in contact with the p type region, the high-concentration region having a higher concentration of p type impurities than the p type region;
forming, by heat-treating the gallium nitride layer to diffuse p type impurities from the high-concentration region to the p type region, a second region having a higher concentration of p type impurities than a first region of the p type region;
forming a gate insulator film on the gallium nitride layer on a side of a first principal face, the gate insulator film being in contact with the first region and the second region;
forming an n type region in the gallium nitride layer on the side of the first principal face opposite to the first region across the second region; and
forming a first electrode, the first electrode being in contact with the n type region.
   (14)

The fabrication method of a nitride semiconductor device according to (13), further including:
before heat-treating the gallium nitride layer,
ion-implanting nitrogen into a region in the gallium nitride layer, the region including an interface between a region where the high-concentration region is to be formed and a region where the second region is to be formed.
   (15)

The fabrication method of a nitride semiconductor device according to (14),
wherein in forming the n type region,
before heat-treating the gallium nitride layer, a mask is formed on the gallium nitride layer on the side of the first principal face and an n type impurity is ion-implanted into a region in the gallium nitride layer, the region not being covered by the mask, and
wherein in ion-implanting the nitrogen,
the nitrogen is ion-implanted into the gallium nitride layer using the mask.
   (16)

The fabrication method of a nitride semiconductor device according to (15),
wherein in ion-implanting the nitrogen,
the nitrogen is ion-implanted at an inclined angle relative to a direction normal to the first principal face.
   (17)

The fabrication method of a nitride semiconductor device according to any one of (13) to (16), wherein the highest temperature in heat-treating the gallium nitride layer is 1300° C. or higher.

### REFERENCE SIGNS LIST

1, 1A, 1B, 1C, 1D, 1E vertical MOSFET
10 GaN substrate
10a front surface
10b rear surface
11 GaN monocrystalline substrate
12 GaN layer
13 well region
13′ well-forming region
14 high-concentration region
14′ high-concentration region forming region
15 contact region
15′ contact-forming region
21 gate insulator film
22 gate electrode
23 source region
23′ source-forming region
25 source electrode
26 drain electrode
41 protective film
100 GaN semiconductor device
121 JFET region
131 first region
132, 132A second region
132′, 132A′ second region forming region
H trench
M1, M2, M11, M12, M21, M31, M32, M33 mask

1. A nitride semiconductor device, comprising:
a gallium nitride layer having a first principal face and a second principal face, the second principal face being located on opposite side of the first principal face; and
a field effect transistor formed in the gallium nitride layer,
the field effect transistor including:
a gate insulator film formed on the gallium nitride layer on a side of the first principal face;
a p type region formed in the gallium nitride layer, the p type region being in contact with the gate insulator film;
an n type region formed in the gallium nitride layer, the n type region being in contact with the p type region in a first direction parallel to an interface between the p type region and the gate insulator film; and
a first electrode disposed on the side of the first principal face, the first electrode being in contact with the n type region,
wherein the p type region includes:
a first region being in contact with the gate insulator film; and
a second region being in contact with the gate insulator film and lying in the first direction between the first region and the n type region,
wherein the second region has a higher concentration of p type impurities than the first region,
wherein the field effect transistor further including:
a p type high-concentration region formed in the gallium nitride layer, the high-concentration region being located between the n type region and the second principal face,
wherein the high-concentration region has a higher concentration of p type impurities than the first region and is in contact with the second region,
wherein the high-concentration region has a higher concentration of p type impurities than the second region.

2. A nitride semiconductor device, comprising:
a gallium nitride layer having a first principal face and a second principal face, the second principal face being located on opposite side of the first principal face; and
a field effect transistor formed in the gallium nitride layer,
the field effect transistor including:
a gate insulator film formed on the gallium nitride layer on a side of the first principal face;
a p type region formed in the gallium nitride layer, the p type region being in contact with the gate insulator film;
an n type region formed in the gallium nitride layer, the n type region being in contact with the p type region in a first direction parallel to an interface between the p type region and the gate insulator film; and
a first electrode disposed on the side of the first principal face, the first electrode being in contact with the n type region,
wherein the p type region includes:
a first region being in contact with the gate insulator film; and
a second region being in contact with the gate insulator film and lying in the first direction between the first region and the n type region,
wherein the second region has a higher concentration of p type impurities than the first region,
wherein the field effect transistor further including:
a p type high-concentration region formed in the gallium nitride layer, the high-concentration region being located between the n type region and the second principal face,
wherein the high-concentration region has a higher concentration of p type impurities than the first region and is in contact with the second region,
wherein the concentration of p type impurities in the high-concentration region is 5×10¹⁸ cm⁻³ or more but less than 1×10²⁰ cm⁻³,
wherein the concentration of p type impurities in the second region is 1×10¹⁸ cm⁻³ or more but less than 5×10¹⁸ cm⁻³, and
wherein the concentration of p type impurities in the first region is 1×10¹⁶ cm⁻³ or more but less than 1×10¹⁸ cm⁻³.

3. The nitride semiconductor device according to claim 1, wherein the first region and the second region exist in a channel region of the field effect transistor.

4. The nitride semiconductor device according to claim 1, wherein an on-state current of the field effect transistor flows from a side of the second principal face of the gallium nitride layer through the first region and the second region to the n type region.

5. The nitride semiconductor device according to claim 1,
wherein a peak position exists in the p type region, the peak position being a position where a concentration of p type impurities is the highest in the first direction,
wherein the peak position exists in the second region.

6. The nitride semiconductor device according to claim 1, wherein the second region is in contact with the n type region.

7. The nitride semiconductor device according to claim 1, wherein the high-concentration region is in contact with the n type region.

8. The nitride semiconductor device according to claim 1, wherein the high-concentration region is in contact with the first electrode.

9. The nitride semiconductor device according to claim 1, wherein the high-concentration region is in contact with the first region.

10. The nitride semiconductor device according to claim 1,
the field effect transistor further including:
a second electrode formed on the side of the second principal face.

11. The nitride semiconductor device according to claim 2, wherein the first region and the second region exist in a channel region of the field effect transistor.

12. The nitride semiconductor device according to claim 2, wherein an on-state current of the field effect transistor flows from a side of the second principal face of the gallium nitride layer through the first region and the second region to the n type region.

13. The nitride semiconductor device according to claim 2,
wherein a peak position exists in the p type region, the peak position being a position where a concentration of p type impurities is the highest in the first direction,
wherein the peak position exists in the second region.

14. The nitride semiconductor device according to claim 2, wherein the second region is in contact with the n type region.

15. The nitride semiconductor device according to claim 2, wherein the high-concentration region is in contact with the n type region.

16. The nitride semiconductor device according to claim 2, wherein the high-concentration region is in contact with the first electrode.

17. The nitride semiconductor device according to claim 2, wherein the high-concentration region is in contact with the first region.

18. The nitride semiconductor device according to claim 2,
the field effect transistor further including:
a second electrode formed on the side of the second principal face.

19. A fabrication method of a nitride semiconductor device, comprising:
forming a p type region in a gallium nitride layer;
forming, in the gallium nitride layer, a high-concentration region in a region being in contact with the p type region, the high-concentration region having a higher concentration of p type impurities than the p type region;
forming, by heat-treating the gallium nitride layer to diffuse p type impurities from the high-concentration region to the p type region, a second region having a higher concentration of p type impurities than a first region of the p type region;
forming a gate insulator film on the gallium nitride layer on a side of a first principal face, the gate insulator film being in contact with the first region and the second region;
forming an n type region in the gallium nitride layer on the side of the first principal face opposite to the first region across the second region; and
forming a first electrode, the first electrode being in contact with the n type region,
wherein the fabrication method further comprises:
before heat-treating the gallium nitride layer,
ion-implanting nitrogen into a region in the gallium nitride layer, the region including an interface between a region where the high-concentration region is to be formed and a region where the second region is to be formed.

20. The fabrication method of a nitride semiconductor device according to claim 19,
wherein in forming the n type region,
before heat-treating the gallium nitride layer, a mask is formed on the gallium nitride layer on the side of the first principal face and an n type impurity is ion-implanted into a region in the gallium nitride layer, the region not being covered by the mask, and
wherein in ion-implanting the nitrogen,
the nitrogen is ion-implanted into the gallium nitride layer using the mask.

21. The fabrication method of a nitride semiconductor device according to claim 20,
wherein in ion-implanting the nitrogen,
the nitrogen is ion-implanted at an inclined angle relative to a direction normal to the first principal face.

22. The fabrication method of a nitride semiconductor device according to claim 19, wherein the highest temperature in heat-treating the gallium nitride layer is 1300° C. or higher.

23. The fabrication method of a nitride semiconductor device according to claim 20, wherein the highest temperature in heat-treating the gallium nitride layer is 1300° C. or higher.

24. The fabrication method of a nitride semiconductor device according to claim 21, wherein the highest temperature in heat-treating the gallium nitride layer is 1300° C. or higher.
